(19) United States
(12) Patent Application Publication
(10) Pub. No.: US 2002/0137346 A1
(43) Pub. Date: Sep. 26, 2002

(54) Workpiece distribution and processing in a high throughput stacked frame

(75) Inventors: Gary R. Donaldson, San Jose, CA (US); William Wang, San Jose, CA (US)

Correspondence Address: Patent Counsel, MS/2061, Legal Affairs Dept., Applied Materials, Inc., P.O. Box 450A, Santa Clara, CA, 95052, US

(73) Assignee: APPLIED MATERIALS. INC.

(21) Appl. No.: 09/804,587

(22) Filed: Mar. 12, 2001

(51) Int. Cl. G06F 19/00; C23F 1/00; H01L 21/306; H01L 21/311

(52) U.S. Cl. 438/694; 438/908; 156/345.32

(57) ABSTRACT

An integrated workpiece vacuum processing system for processing semiconductor workpieces is provided using a stacked chamber design. The processing system comprises a multiple chamber support unit having a plurality of processing chamber support bays arranged in rows and columns wherein a vacuum processing chamber module is received in each support bay and a transfer chamber is coupled to the plurality of processing chamber modules.

### BACKGROUND OF THE INVENTION

1. Field of the Invention

The present invention relates generally to semiconductor processing systems, and more particularly to multiple chamber semiconductor processing systems.

2. Description of the Related Art

The present invention is related to a silicon wafer processing system that includes multiple process chambers. However, until recently, the typical available processing reactor systems were single chamber batch-type systems in which the chamber is dedicated to a single type of process such as plasma etching or chemical vapor deposition. These process-dedicated batch-type reactor chambers were designed to provide a high processing throughput for a single process step. Some of these single chamber etcher systems did include an associated vacuum load lock that was used for pre- or post-processing.

Multiple chamber systems are relatively new to the art. An article entitled “Dry Etching Systems: Gearing Up for Larger Wafers”, in the October, 1985 issue of Semiconductor International magazine, pages 48-60, describes a four-chamber dry etching system in which a robot in a pentagonal-shaped housing serves four plasma etching chambers and a cassette load/unload load lock port mounted on the robot housing. More recently, U.S. Pat. No. 5,882,165 describes a four-chamber multiple processing chamber in a pentagonal-shaped housing which is capable of performing distinctly different type of processing simultaneously or sequentially in the different chambers. In such semiconductor processing systems, in order to decrease contamination and to enhance through-put, such systems often utilize one or more robots under a closed, vacuum system to transfer semiconductor wafers and other workpieces between a number of different vacuum chambers which perform a variety of tasks.

However, because of the relatively large number of chambers and the irregular pentagonal shape, the system as a whole can occupy a substantial amount of floor space. This is especially true when these pentagonal shaped processing systems are used in conjunction with more pentagonal shaped tools as additional processes are added in series with the processes performed in the single processing system. This can be a particular problem in locations where land is very scarce and/or very expensive. In addition, because wafer processing is preferably performed in clean room conditions, providing a sufficiently large clean room can further substantially increase costs. This is exacerbated when the wafer diameter increases above the current 200 mm diameter commonly used in semiconductor manufacturing.

### SUMMARY OF THE PREFERRED EMBODIMENTS

An integrated workpiece vacuum processing system and method for processing semiconductor workpieces is provided. In one embodiment, the processing system comprises a multiple chamber support unit having a plurality of processing chamber support bays arranged in at least two rows and two columns wherein a vacuum processing chamber module is received in each support bay and a transfer chamber is coupled to the plurality of processing chamber modules. In another embodiment, at least three processing chamber support bays are arranged in one column wherein a vacuum processing chamber module is received in each chamber support bay.

In another aspect, the processing chamber modules located on the same column perform the same processing step to the workpieces.

In yet another aspect, the processing chamber modules can be inserted or removed from said processing unit.

### BRIEF DESCRIPTION OF THE DRAWINGS

FIG. 1 is a simplified schematic front plan view of a multiple chamber support unit in accordance with one embodiment;

FIG. 2 is a cross-sectional front view of a multiple chamber support unit in accordance with one embodiment where the vacuum processing chamber modules are received in each support bay;

FIG. 3 is a cross-sectional side view in accordance with one embodiment;

FIG. 4 is a cross-sectional side view in accordance with an alternative embodiment;

FIG. 5 is a simplified cross-sectional view from the top of the chamber support unit showing the relations between the support bays, the processing modules, the transfer robot, and the load locks in accordance with one embodiment;

FIG. 6 is a cross-sectional top view of a processing chamber support bay in accordance with one embodiment; and

FIG. 7 is a simplified schematic front plan view of a multiple chamber support unit in accordance with an alternative embodiment.

### DETAILED DESCRIPTION OF THE PREFERRED EMBODIMENTS

In the following description, reference is made to the accompanying drawings which form a part hereof and which illustrate several embodiments of the present invention. It is understood that other embodiments may be utilized, and structural and operational changes may be made, without departing from the scope of the present invention.

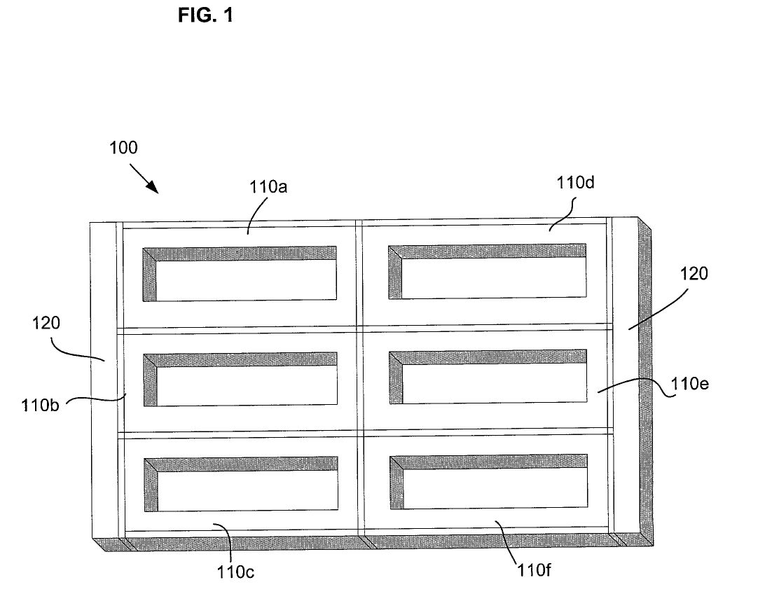

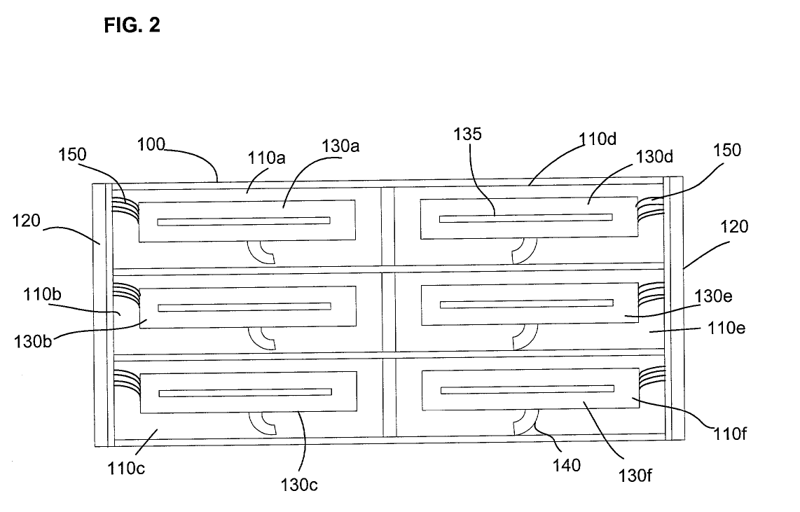

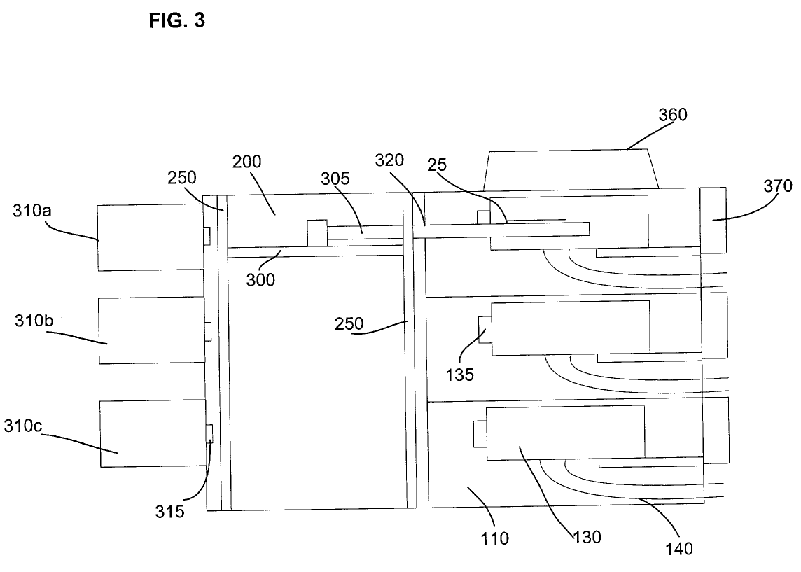

FIG. 1 depicts a frontal schematic view of a multiple chamber support unit 100 according to one embodiment of the present invention. The support unit 100 contains multiple support bays 110 arranged in a stacked array formation of columns and rows. FIG. 1 shows an embodiment having two columns and three rows, but any number of columns or rows can be used in the stacked array formation. For example, in alternative embodiments, a single column of support bays 110 can be used. Each support bay 110 is capable of housing an individual vacuum processing chamber module 130 (FIG. 2). In the illustrated embodiment, six such support bays 110a, b, c, d, e, f are depicted. It is recognized, however, that fewer or greater numbers of support bays may be utilized to accommodate greater or fewer numbers of processing chamber modules 130 depending upon the particular application. Gas panels 120 are attached to each side of the support unit 100 to provide clean air to the support bays 110 and supply the appropriate gases, vapour, liquids or other chemicals for the processing steps performed in the chamber modules 130. The gas panels 120 are equipped with air inlet and air outlet ports, filters, fans, etc. which are standard in the industry to provide a clean air environment for a semiconductor processing apparatus. Attached to the support bays 110 is a transfer chamber 200 (FIG. 3), which has a plurality of load lock ports 310. The transfer chamber 200 will be described in greater detail below in conjunction with FIG. 3. The chamber support unit 100 has a plurality of access ports 320 between the transfer chamber 200 and each of the support bays 110, as well as access ports 315 between the transfer chamber 200 and the load lock ports 310. Additional access ports 135 are located at the entrance of each processing chamber module 130. Each access port 135, 315, or 320 has a slit valve which may be opened to permit a wafer 25 or other workpiece, such as a panel, to pass from one chamber through the access port to an adjoining chamber/support bay/load lock port/etc., or may be closed to close the access port 135, 315, or 320 in a pressure tight seal. Suitable slit valves are described in issued U.S. Pat. No. 4,785,962, which is incorporated herein by reference. In alternative embodiments, one or more access ports may not be needed. For example, if the support bays 110 are not to be sealed off from the transfer chamber 200, access ports 320 are not needed.

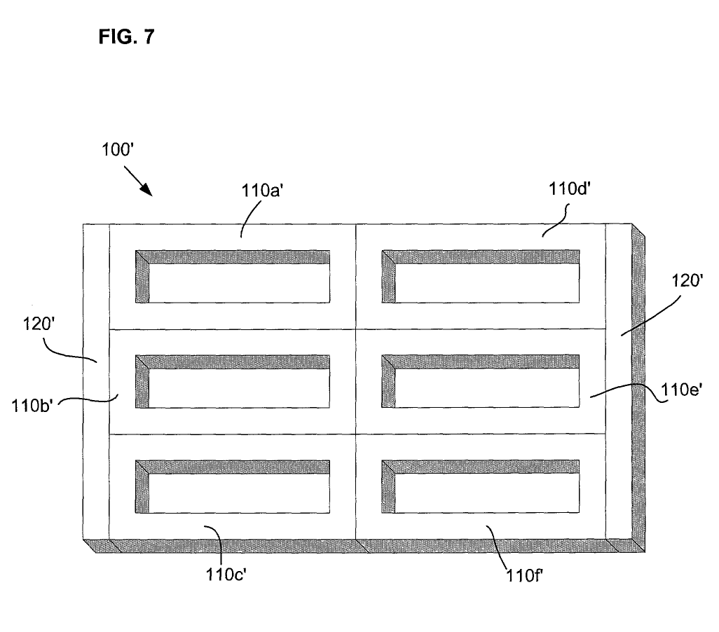

In one embodiment, the support bays 110 are designed using a modular approach for ease of construction and maintenance. Additionally, by having modular support bays 110, support unit 100 can easily be modified during manufacturing to have additional columns and rows depending on the number of processing steps desired to be performed within a single chamber support unit 100. Each support bay 110 in a particular column of the array, is preferably the same size and shape as the other bays 110 in that column, to facilitate stacking the support bays 110 in a stacked array. The support unit 100 may include a separate rack support frame 100a to which the support bays are attached in columns and rows as seen in FIG. 1. Alternatively, the support bays 110 may be fastened directly to each other, obviating the need for a separate supporting frame as seen for the bays 110a′-110f′ in FIG. 7.

Moreover, in preferred embodiments, each support bay 110 and the transfer chamber 200 can be constructed using separate monoliths, i.e. a frame machined or otherwise fabricated from one piece of material such as aluminum. The use of monolithic construction facilitates alignment of the individual support bays 110 and also reduces or eliminates difficulties in sealing the individual support bays 110. The chamber support unit 100 and the individual support bays 110 may then be joined together in pressure-tight joints. Alternatively, the entire support unit 100 can be constructed as a monolith.

FIG. 2 depicts a cross-sectional front view of the support unit 100 with the vacuum processing chamber modules 130a, b, c, d, e, f received in each support bay 110a, b, c, d, e, f, respectively. Each chamber module 130 may be adapted for various types of processing including processes such as etching and deposition. In preferred embodiments, the processing steps in the chamber modules 130 are performed in parallel. In other words, the processing chamber modules 130 located along the same column of support bays 110a, b, c or 110d, e, f perform the same processing step. Thereby, in preferred embodiments, a two column support unit 100 performs two types of processing steps within the support unit 100. The number of rows, on the other hand, indicates the number of wafers 25 that can be processed simultaneously in a selected column of the support unit 100. Therefore, in the illustrated embodiment of FIG. 2, three wafers 25 can simultaneously undergo first one process step in one column of processing modules and then a second process step in the other column of processing modules. This stacked or rack approach to processing wafers 25 permits the “footprint,” that is the total floor space occupied by the support unit 100, to be substantially reduced notwithstanding the large number of chamber modules 130. Moreover, the close vicinity of each chamber module 130 in the support bays 110 can permit improved isolation of the chamber modules 130 providing improved throughput and product quality.

Although the preferred embodiments perform the same processing steps along the same column of the support unit 100, it is appreciated that different processes can be performed along a single column, and the wafers 25 on different rows need not proceed along the order of the process steps in lock step. Further, such chamber modules 130 can also be dedicated to pre-processing treatments such as etch cleaning or heating a wafer or both. Alternatively, one or more of the chamber modules 130 may be used for post-processing treatments (such as cooling).

In preferred embodiments, each support bay 110 is equipped with appropriate power and chemical sources as well as feed lines 150 to supply the chamber module 130 with feeds such as: gas, chemical and electrical (including RF) feeds which are appropriate for providing the materials and energy to particular processes performed in the chamber module 130. Moreover, each chamber module 120 is equipped with forelines 140 to exhaust the chamber module 130 of the gas or other chemical used during the process steps performed in the chamber module 130. In addition, the forelines 140 also can be connected to a separate vacuum pump (not shown) to increase the vacuum environment in each chamber module 130.

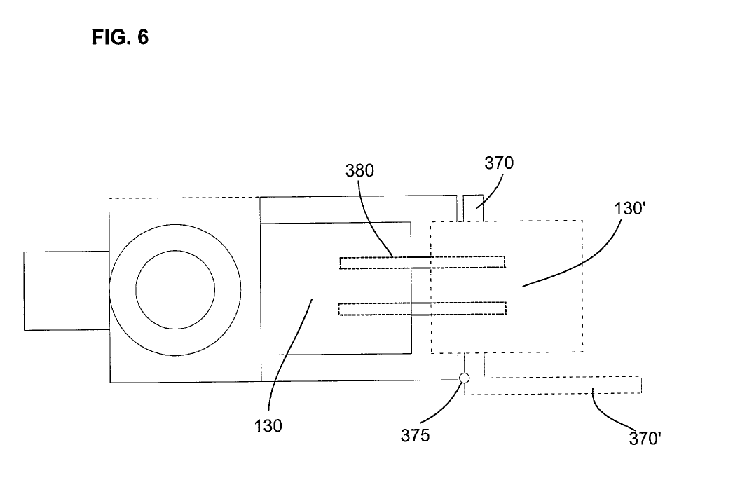

Additionally, in preferred embodiments, the chamber modules 130 are designed to be slidably engaged with the support bays 110. The chamber modules 130 can be pulled out of the support bay 110, in the manner of a file cabinet drawer, for maintenance or routine cleaning. In addition, the feed lines 150 and forelines 140 are designed to disconnect quickly from the chamber modules 130 when the chambers are removed from the support bays 110 for maintenance or cleaning. Additional detail of the maintenance process will be discussed below in conjunction with FIG. 6.

FIG. 3 is a cross-sectional side view in accordance with a preferred embodiment. As mentioned above, a transfer chamber 200 is attached to the support bays 110. Communicating slits 320 are provided between the transfer chamber 200 and the individual support bays 110 wherein a door is provided for sealing each of these slits 320 when the access to the support bays 110 is to be sealed off. Inside the transfer chamber 200 is a magnetically levitated robot assembly 300. The robot assembly 300 is used to transfer the wafers 25 from the loadlock ports 310 to the chamber modules 130. In preferred embodiments, the robot assembly 300 includes vertical tracks 250 located near the side walls of the transfer chamber 200. Magnetic force is applied to raise or lower the base of the robot arm 305 along the track to the precise height needed for wafer 25 placement. The robot arm 305 is preferably a telescoping robot arm comprised of concentric shafts wherein each inner shaft is slidably engaged within an outer shaft. The robot arm 305 extends as the shaft assembly expands, and retracts as the shaft assembly contracts. Alternatively, the robot arm 305 may be articulated to fold and unfold to the appropriate length needed to place the wafer inside the chamber module 130. Other types of robot arms may be used to precisely place the wafers 25 inside the chamber modules 130 through the appropriate slits 135. It is preferred that the robot assembly 300 have a long reach, a minimum of gears or other moving parts, and effective sealing for high vacuum environments used in processes such as physical vapor deposition.

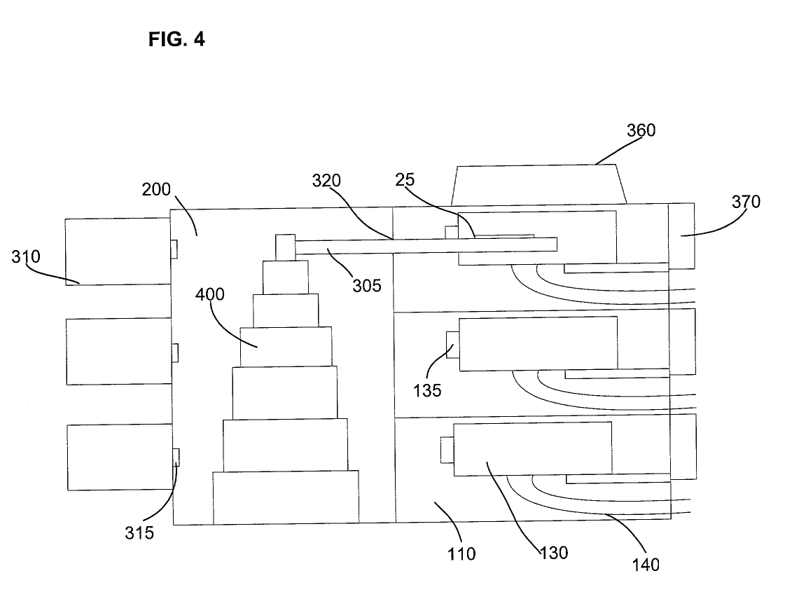

In alternative embodiments, the magnetically levitated robot assembly 300 in FIG. 3 may be replaced by a telescoping robot assembly 400 in FIG. 4. The telescoping robot assembly 400 is comprised of concentric shafts which allow the robot arm 305 to telescope to different levels within the transfer chamber 200. Each inner shaft is slidably engaged within each outer shaft, allowing the robot arm 305 to vertically climb as the shaft assembly expands. Moreover, the innermost shaft is mounted by journal bearings within the last shaft allowing the innermost shaft to be rotated, typically by stepper motor-controlled cable and drum drive mechanisms. The operation of the stepper motors (not shown) is controlled by the system controller/computer 360. The combined horizontal movement of the robot assembly 300, rotational motion of the innermost shaft, and telescoping length of the robot arm 305 inserts the robot blade through the slit valve doors 320 into a selected process chamber module 130. As seen in the alternative embodiment of FIG. 4, any variety of suitable pneumatic and electromechanical mechanisms can be used for the vertical movement of the robot arm 305. Other suitable mechanisms for elevating the wafers 25 include mechanisms exterior to the transfer chamber 200 which are magnetically coupled to the robot arm 305.

The robot arm 305 is adapted to firmly hold a wafer 25 to/from the load lock 310 from/to the chamber modules 130. In the preferred embodiment, the robot arm 305 comprises a robot blade, but it is recognized that any of a variety of known devices for securing a wafer 25 during transport may be used including electrostatic chucks, plates, and pockets. Moreover, in preferred embodiments, the robot arm 305 has dual over/under action allowing the robot arm 305 to deliver and pick up wafers 25 simultaneously. In addition, the robot arm 305 can be equipped with a heating plate for heating the wafer 25 prior to processing in the chamber modules 130. Alternatively, the robot arm 305 may have a cooling plate to cool the wafer after processing. Other types of treatment may also be performed in the transfer chamber 200 depending on the particular application.

As seen in FIG. 3, coupled to access ports on the opposite side of the transfer chamber from the support bays 110 is a plurality of load lock ports 310 which include wafers to be processed or wafers already processed. The robot assembly 300 unloads an unprocessed wafer 25 from one of the load lock ports 310 and transfers the wafer 25 for processing. Once the processing is complete, the robot assembly 300 places the processed wafer 25 into an empty slot in one of the load lock ports 310. In the illustrated example, there are six load lock ports 310a, b, c, d, e, f (310d, e, and f not shown in FIG. 3) located opposite of each support bay 110a, b, c, d, e, f. Three of the load lock ports 310a, b, c are filled with unprocessed wafers 25, while the other three load lock ports 310d, e, f are left empty. For illustration purposes, one typical operational cycle of wafer transport through the support unit 100 can be as follows. Initially, the robot assembly 300 picks up an unprocessed wafer from load lock port 310c and transports the wafer 25 to processing module 130c. Similarly, the robot assembly 300 then picks up another unprocessed wafer from different load lock port 310b and transports the wafer 25 to processing module 130b. Lastly, the robot assembly 300 picks up a third unprocessed wafer from load lock port 310a and transports the wafer 25 to processing module 130a. Alternatively, the robot assembly 300 can pick up all three unprocessed wafers from a single load lock port 310, and pick up additional unprocessed wafers from the other load lock ports 310 as the first load lock port is emptied. Once the wafers 25 are placed in processing modules 130a, b, c, the wafers are processed (e.g. etched).

After the process is completed in modules 130a, b, c, the robot assembly 300 can transfer the wafers selectively to another chamber module for additional processing. In the illustrated example, the robot assembly 300 transports the wafer in module 130a to module 130d. Similarly, the robot assembly 300 transports the wafers in modules 130b and c to modules 130e and f, respectively. Upon the completion of the second process on the wafers 25 (e.g. deposition), the robot assembly 300 returns the processed wafers to the appropriate load lock port 310d, e, or f, whether one in each load lock port 310d, e, and f or all three processed wafers in a single load lock port 310d, e, or f. Alternatively, the transfer chamber can post-process treat the wafer such as cooling it before or while transferring it to load lock port 310. After a load lock port 310d, e, f is filled with processed wafers, the slit valve of the access port for that load lock is closed. It is appreciated that a different number of load lock ports 310 can be used with the preferred embodiments. For example, a single load lock port 310 can be used where the robot assembly 300 takes unprocessed wafers from the load lock port to fill each processing module 130, and then returns the processed wafers to the same load lock port.

In preferred embodiments, the chamber support unit 100 uses a nodal architecture to process the wafers 25, where the control duties are spread amongst a plurality of nodal controllers located throughout the support unit 100. For example, the controls of the chamber support unit 100 are run primarily from the controller/computer 360 including the robot assembly 200, the load locks 310, and the access ports. However, the individual climate and processing steps of the chamber modules 130 are controlled by its respective controller 370, where the necessary process steps are programmed into the controllers 370. In alternative embodiments, additional, separate controllers can be used for individual functions such as the robot assembly 300, maintaining vacuum levels, etc.

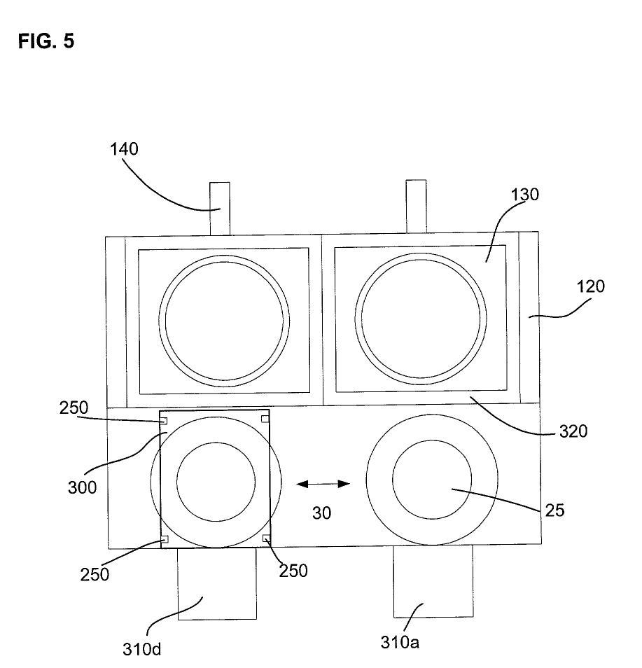

FIG. 5 is a simplified cross-sectional view from the top of the chamber support unit showing the spatial relationships between the support bays, the processing modules, the transfer robot, and the load locks in accordance with one embodiment. The robot assembly 300 is shown to be capable of moving parallel to the support bays 110 along the line 30 to deliver the wafers 25 from the various load lock ports 310 to the individual processing modules 130. As best seen in FIG. 5, the footprint of the system is substantially reduced by using the rack configuration. Moreover, due to the array-type configuration, each chamber stage can be isolated more easily from all the other chambers (e.g. load locks 310, the transfer chamber 200). Preferably, none of the chambers or stages is vented to atmosphere during processing. In addition, during wafer transfer, preferably, only one slit valve is open at one time. As a result, variations in vacuum level during wafer transfer can be minimized by using a vacuum pumping system (not shown), to provide a vacuum gradient across the system from the load locks 310 to the vacuum processing modules 130. The staged vacuum is applied across the system by a suitable pump system (not shown) with the degree of vacuum increasing in order from the load locks 310 to the processing chamber modules 130. Consequently, the time required to pump down load lock port 310 to its base vacuum level subsequent to the loading of a wafer therein is minimized and very high degrees of vacuum can be used in the chamber modules 130 without lengthy pump down times and, thus without adversely affecting system throughput. Consequently, product quality and throughput are maintained while the footprint is substantially reduced.

FIG. 6 is a cross-sectional top view of a processing chamber support bay in accordance with one embodiment. FIG. 6 illustrates the capability for the chamber modules 130 to be removed for maintenance or routine cleaning. The individual controllers 370 are mounted to the support bay 110 on swing out hinges 375 and act as a back door to the support bays 110. As explained previously, the chamber modules 130 are designed to be slidably engaged with the support bays 110. Once the controller 370 is opened (seen as controller 370′), the chamber module 130 can be pulled out of the support bay 110 on supporting rails 380 in a manner similar to a file cabinet drawer for maintenance or routine cleaning (seen as chamber module 130′). Other types of sliding support can be used such as wheels, ball bearings, etc. Moreover, the forelines 140 and feed lines 150 are coupled to the chamber modules 130 using standard couplers (not shown). The standard couplers allow the forelines 140 and feed lines 150 to be readily disconnected, and thereby providing easier access to each individual support bay 110 for maintenance.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims rather than the foregoing description, and all changes which come within the meaning and range of equivalency of the claims are therefore intended to be embraced therein.

What is claimed is:

1. An integrated workpiece vacuum processing system for processing semiconductor workpieces, comprising:
a multiple chamber support unit having a plurality of processing chamber support bays arranged in at least two rows and two columns;
a first vacuum processing chamber module received in a first processing chamber support bay on a first row and a first column of said support unit;
a second vacuum processing chamber module received in a second processing chamber support bay and arranged horizontally adjacent to the first vacuum processing chamber module on said first row and a second column of said support unit;
a third vacuum processing chamber module received in a third processing chamber support bay and arranged vertically adjacent to the first vacuum processing chamber on the first column and a second row of said support unit;
a fourth vacuum processing chamber module received in a fourth processing chamber support bay and arranged vertically adjacent to the second vacuum processing chamber on the second row and the second column of said support unit; and
a transfer chamber coupled to a plurality of said processing chamber modules.

2. The system of claim 1, further comprising:
a robot in said transfer chamber for transporting workpieces between the first and second row and the first and second column.

3. The system of claim 1, further comprising a monolithic structure which includes the at least two rows and two columns of said support unit.

4. The system of claim 1, further comprising a monolithic structure which includes the at least two rows and two columns of said support unit and the transfer chamber.

5. The system of claim 1, wherein the at least two rows and two columns of the support unit are modular.

6. The system of claim 1, wherein the processing chamber modules located on the same column perform the same type of processing step to the workpieces.

7. The system of claim 1, wherein the processing chamber modules are slidably carried by each support bay so that each chamber module can be selectively inserted and removed from said support unit.

8. A method for processing semiconductor workpieces in an integrated workpiece vacuum processing system, comprising:
processing workpieces in a first plurality of vacuum processing chamber modules received inside a first column of support bays;
transferring the workpieces from said first plurality of vacuum processing chamber modules to a second plurality of vacuum processing chamber modules received inside a second column of support bays arranged horizontally adjacent to said first column; and
processing the workpieces in said second plurality of vacuum processing modules.

9. The method of claim 8, further comprising:
transferring workpieces from a load lock port to said first plurality of vacuum processing chamber modules before processing; and
transferring workpieces from said second plurality of vacuum processing chamber modules to a load lock port after processing.

10. The method of claim 8, wherein the processing chamber modules located on the same column perform the same type of processing step to the workpieces.

11. The method of claim 8, further comprising:
slidably removing the vacuum processing chamber module from the support bay for subsequent maintenance.

12. The method of claim 8, wherein the support bays are modular.

13. The method of claim 8, wherein a robot transfers the workpieces from said first plurality of vacuum processing chamber modules to said second plurality of vacuum processing chamber modules.

14. The system of claim 2, wherein the robot is a magnetically levitated robot.

15. The method of claim 8, further comprising:
processing workpieces simultaneously in vacuum processing chamber modules located in a same column of support bays.

16. An integrated workpiece vacuum processing system for processing semiconductor workpieces, comprising:
a multiple chamber support unit having at least three processing chamber support bays arranged in one column;
for each chamber support bay, a vacuum processing chamber module received in said chamber support bay; and
a transfer chamber coupled to a plurality of said processing chamber modules.

17. The system of claim 16, wherein the processing chamber modules located on the one column perform the same type of processing step to the workpieces.

18. The system of claim 16, wherein the processing chamber modules are slidably carried by each support bay so that each chamber module can be selectively inserted and removed from said support unit.

19. A method for processing semiconductor workpieces in an integrated workpiece vacuum processing system, comprising:
processing workpieces in at least three vacuum processing chamber modules received inside a column of support bays.

20. The method of claim 19, wherein the processing chamber modules located on the same column perform the same type of processing step to the workpieces.

21. The method of claim 19, further comprising:
slidably removing the vacuum processing chamber module from the support bay for subsequent maintenance.
